(19) United States
(12) Patent Application Publication
(10) Pub. No.: US 2009/0167123 A1
(43) Pub. Date: Jul. 2, 2009

(54) EXTERNAL HARD DISK BOX WITH AN EXTENSION DEVICE

(76) Inventor: Brian Hsu, Taipei Hsien (TW)

Correspondence Address: BRIAN HSU, 235 Chung - Ho, Box 8-24, Taipei, 235, TW

(21) Appl. No.: 12/050,955

(22) Filed: Mar. 19, 2008

(30) Foreign Application Priority Data
Dec. 28, 2007 (TW) 096222296

(51) Int. Cl. H05K 5/00; A47B 81/00; H05K 7/00; G06F 1/16

(52) U.S. Cl. 312/223.2

(57) ABSTRACT

An external hard disk box with an extension device includes an external box with a hard disk and a receptacle. The external box has a control panel. The receptacle has a slot compatible to a portable device and a conduction portion. The conduction portion is built in the slot and has an electric specification compatible to the portable device. A signal line serves to connect the conduction portion with the control panel so that the portable device could share the resource of the hard disk in the external box for extending data accessing space.

### FIELD OF THE INVENTION

The present invention relates to hard disks, in particular to an extension device connected to an external hard disk box for providing extending data accessing space of a device.

### BACKGROUND OF THE INVENTION

With the increasing capacity of an electronic storage media, the relative applications become more popular and practical. Such as a digital camera, a digital walkman (like an IPOD), a PDA a mobile phone (such as an I Phone), and other consuming electronics are benefited by the better function and entertainment and so being widely used.

To edit or access the data of the devices, a user will be restricted by the limit of the memory or the devices must connect to a PC and then lose the mobility thereof.

Further, for example, the popular I Pod or I Phone of the Apple is equipped a capacity of 4 GB, 8 GB, or 16 GB memory in the beginning. A consumer has to pay nearly double the price to have an advanced specification of 80 GB, or 160 GB. It's a heavily load to a consumer.

### SUMMARY OF THE INVENTION

Accordingly, the primary object of the present invention is to provide an extension device which is connected to an external box with a hard disk therein to support a digital camera, a digital walkman (like an IPOD), a PDA, and a mobile phone (like a I Phone), and other consuming electronics for the purpose of extending the memory and a convenience of carrying. And to provide a lower cost solution for a user to enjoy all the function, interface and entertainment during operating of the portable device without being restricted is a primary objective of the present invention.

To achieve above objects, the present invention provides an external box and a receptacle. The external box has a control panel therein. The receptacle has a slot which is compatible to a portable device and a conduction portion which is built in the slot and has an electric specification compatible to the portable device. A signal line serves to connect the conduction portion and the control panel so that the portable device may share the resource of the hard disk in the external box for extending data accessing space.

Furthermore, a lateral portion of the receptacle has a buckle, and a retaining portion of the external box is relative to the buckle, thus the external box and the receptacle can be assembled in one through the connection between the retaining portion and the buckle. This function can provide a convenience of carrying, and through the function the portable device can stand on a surface, thus the user can easily observe the information provided by the portable device and save the space of a surface of a table. This is another objective of the present invention.

Comparing with the prior art, the benefits of the present invention including:

1. A portable device sharing the data accessing space of a hard disk without connecting to a PC and affecting the mobility of the portable device.

2. A lower and economic cost to achieve the need of a user than the same specification which is provided by the portable device.

3. An easily observing of information and easily operating of the interface provided by a portable device by standing a portable device on a surface of a table under a saving of the space.

The various objects and advantages of the present invention will be more readily understood from the following detailed description when read in conjunction with the appended drawing.

The various objects and advantages of the present invention will be more readily understood from the following detailed description when read in conjunction with the appended drawing.

### BRIEF DESCRIPTION OF THE DRAWINGS

FIG. 1 shows a main structure of the present invention.

FIG. 2 is a schematic view showing the application of the present invention.

FIG. 3 is another second schematic view showing another application of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

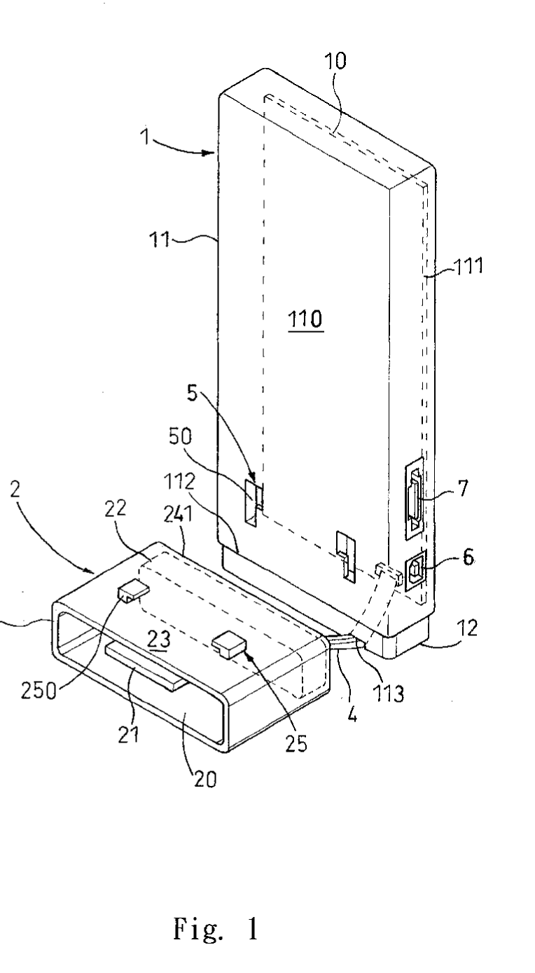

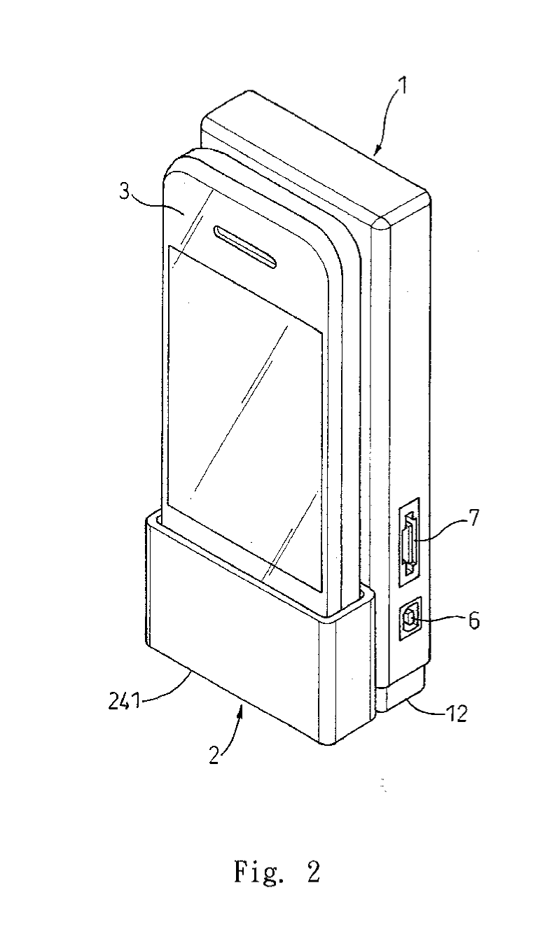

Referring to FIGS. 1 and 2, an external hard disk box with an extension device is illustrated. The external hard disk box has an external box 1 and a receptacle 2. The external box 1 has a control panel 10 therein for controlling and transmitting signals connected. The receptacle 2 has a first slot 20 compatible to a portable device and a conduction portion 21 built in the first slot 20 and having an electric specification compatible to the portable device. A signal line 4 serves to connect the conduction portion 21 and the control panel 10 of the external box 1 so that the portable device 3 may share the resource of the hard disk in the external box 1.

The external box 1 has a body 11 and an insertion portion 12. The body 11 includes at least one surface portion 110, a first lateral side 111 enclosing the surfaces portion 110 and a second lateral side 112 at a lower side of the surface portion 110. The surface portion 110 has a retaining portion 5 at a front side thereof. As illustrated in the drawing, the retaining portion 5 has an approximate L shape hole 50. The first lateral portion 111 is arranged with a power insertion hole 6 of the external box 1 and a slot 7 for supporting a USB interface. The signal wire 4 extends from the second lateral portion 112 and is connected to the receptacle 2.

The insertion portion 12 of the external box 1 is connected to the second lateral portion 112 of the body 11, and the insertion portion 12 has a notch 113. The the signal wire 4 passes through the notch 113. The volume of the insertion portion 12 is smaller than that of the body 11, and thus it is compatible to the receptacle 2.

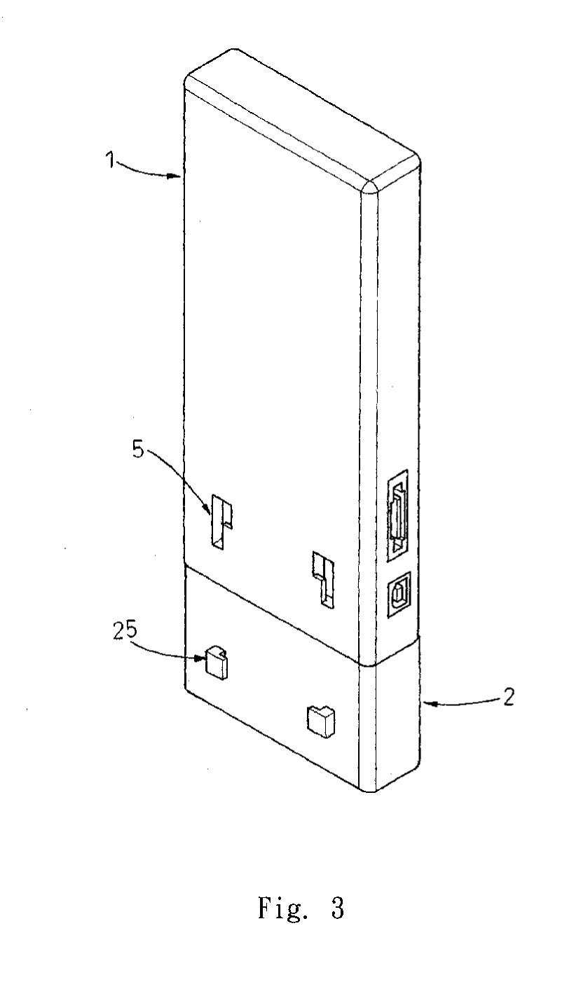

The receptacle 2 has at least one surface portion 23, a first lateral portion 240 at a front side of the surface portion 23 and a second lateral portion 241. The second lateral portion 241 is arranged at an rear side of the surface portion 23, opposite to the first lateral portion 240 and extending from an outer edge of the surface portion 23. The first lateral portion 240 has a first slot 20 compatible for a portable device 3 mentioned above, and the opposite second lateral portion 241 near the insertion portion 12 of the body 1 has a second slot 22 which is compatible to the insertion portion 12. The capacity of the second slot 22 is slightly bigger than that of the insertion portion 12, as shown in FIG. 3, the second slot 22 is insertable by an outer edge of the insertion portion 12 for the user's convenience of carrying.

The surface portion 23 of the receptacle 2 has a buckle 25 which is compatible to the retaining portion 5. An approximate L shape guide 250 of the buckle 25 is arranged to be relative to the approximate L shape hole 50 of the retaining portion 5. Through the connection between the buckle 25 and the retaining portion 5, the surface portion 23 of the receptacle 2 can be attached to the surface portion 110 of the external box 1, and the second lateral side 24 1 of the receptacle 2 is coplanar to the second lateral 112 of the external box 1 or the insertion portion 12. Thus the external box 1 can steadily stand on a surface of table through the receptacle 2 and the insertion portion 12 as shown in FIG. 2, so a user can insert a portable device to the receptacle 2 and observe the information or operate the interface of the portable device.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An external hard disk box with an extension device comprising:
an external box with a hard drive inside and a receptacle, the external box having a body; the body including at least one surface portion, a first lateral side enclosing the surface portion and a second lateral side vertically extended from a lower edge of the surface portion;
a control panel installed in the external box for controlling and transmitting signals;
the receptacle having at least one surface portion, a first lateral portion at a front edge of the surface portion and a second lateral portion extending from a rear side edge of the surface portion, and the first lateral portion having a first slot compatible for a portable device, a conduction portion built in the first slot and having an electric specification compatible to the portable device; a signal line serving to connect the conduction portion and the control panel of the external box so that the portable device is capable of sharing the resource of the hard disk in the external box.

2. The external hard disk box with an extension device as claimed in claim 1, wherein the surface portion has a retaining portion, and the surface portion of the receptacle has a buckle which is compatible to the retaining portion; through the connection between the buckle and the retaining portion, the surface portion of the receptacle is attachable to the surface portion of the external box.

3. The external hard disk box with an extension device as claimed in claim 2, wherein the second lateral side of the receptacle is coplanar to the second lateral of the external box through the connection of the external box and the receptacle so that the external box can steadily stand on a surface of a table by a lateral portion.

4. The external hard disk box with an extension device as claimed in claim 1, wherein the insertion portion is connected to the second lateral portion of the body; the second lateral portion of the receptacle is arranged to be near the insertion portion of the external box, and has a second slot compatible to the insertion portion of the body; a capacity of the second slot is slightly bigger than that of the insertion portion, and thus the second slot is insertable by an outer edge of the insertion portion.

5. The external hard disk box with an extension device as claimed in claim 2, wherein the insertion portion is connected to the second lateral portion of the body; the second lateral portion of the receptacle is arranged to be near the insertion portion of the external box, and has a second slot which is compatible to the insertion portion of the body; a capacity of the second slot is slightly bigger than that of the insertion portion, and thus the second slot is insertable by an outer edge of the insertion portion.

6. The external hard disk box with an extension device as claimed in claim 5, wherein the second lateral portion of the receptacle is coplanar to the insertion portion of the external box through the connection between the external box and the receptacle, so that the external box can steadily stand on a surface of table by a lateral portion.

7. The external hard disk box with an extension device as claimed in claim 1, wherein the first lateral portion of the external box is arranged with a power insertion hole of the external box and a slot for supporting a USB interface.

8. The external hard disk box with an extension device as claimed in claim 2, wherein the retaining portion of the external box is an approximate L shape hole, and the buckle has an approximate L shape guide rod corresponding to a shape of the retaining portion.

9. The external hard disk box with an extension device as claimed in claim 5, wherein the retaining portion of the external box is an approximate L shape hole, and the buckle has an approximate L shape guide rod corresponding to a shape of the retaining portion.
